(19) United States
(12) Patent Application Publication
(10) Pub. No.: US 2003/0221616 A1
(43) Pub. Date: Dec. 4, 2003

(54) Magnetically-actuatable throttle valve

(75) Inventors: Craig M. Carpenter, Boise, ID (US); Ross S. Dando, Nampa, ID (US); Randy W. Mercil, Boise, ID (US); Philip H. Campbell, Meridian, ID (US)

Correspondence Address: WHYTE HIRSCHBOECK DUDEK S.C., 111 E. WISCONSIN AVE., SUITE 2100, MILWAUKEE, WI, 53202, US

(73) Assignee: Micron Technology, Inc., Boise, ID (US)

(21) Appl. No.: 10/156,382

(22) Filed: May 28, 2002

(51) Int. Cl. C23C 16/00

(52) U.S. Cl. 118/715; 156/345.29; 251/65

(57) ABSTRACT

A pressure-regulating device for use with a vapor reaction chamber, and methods of its use, are disclosed. In one embodiment according to the invention, the device comprises a magnetically-actuatable valve having an aperture, a plug containing a plug magnet within the valve, a magnet disposed around the valve and magnetically associated with the plug magnet, and an actuator associated with the magnet. The actuator moves the magnet to magnetically bias the plug magnet thereby moving the plug into and out of sealing engagement with the aperture and regulating pressure within the reaction chamber. Plug movement is achieved without interconnecting mechanical parts disposed through the body of the valve that provide surfaces on which adduct, from depositing vaporous by-product material, can accumulate. Since magnetic interaction moves the plug rather than mechanical parts attached to the valve body, build-up of adduct on the internal surfaces of the valve is reduced.

### FIELD OF THE INVENTION

The present invention generally relates to a throttle valve for use within a semiconductor deposition apparatus. In one aspect, the invention comprises a magnetically-actuatable throttle valve for use with a deposition apparatus to inhibit accumulation of material within the throttle-valve.

### BACKGROUND OF THE INVENTION

Numerous deposition and etching apparatuses are used within a semiconductor manufacturing process. One apparatus frequently used is a chemical vapor deposition (CVD) apparatus. In the CVD apparatus, one or more gases is introduced into a reaction chamber where the gases are mixed and reacted together to produce a vapor that deposits as a film upon a surface of a semiconductor substrate, typically a semiconductor wafer. By-products (i.e., vaporous materials) of the reaction, including any gases that failed to react, are then removed from the reaction chamber.

In order to regulate pressure within the reaction chamber, a throttle vacuum valve is typically employed. However, moving and sliding parts in the vacuum throttle valve are susceptible to the build-up of adduct when by-product is released from the reaction chamber and can create trap areas that adversely affect mean time between failures (MTBF). Adduct formation, as well as a few undesirable effects caused by adduct accumulation, is discussed in U.S. Pat. No. 5,691,235 (Meikle, et. al.). Adduct build-up on the moving and sliding surfaces can also be troublesome in tight tolerance areas within the throttle valve, causing the throttle valve to gum-up and/or lock-up. This requires removal of the throttle valve for cleaning and downtime for the affected chamber.

Thus, an improved pressure control mechanism for use with a semiconductor deposition apparatus that overcomes such problems would be highly desirable.

### SUMMARY OF THE INVENTION

In one aspect, the invention provides a pressure-regulating device for use with a reaction chamber. In one embodiment, the device includes a valve having a valve aperture, a plug comprising a plug magnet disposed within the valve, a ring magnet disposed about the valve, and an actuator associated with the ring magnet. The actuator is operable to move the ring magnet along the valve to magnetically bias the plug magnet. Thus, the plug can be moved into or out of a sealing engagement with the valve aperture to regulate pressure within the reaction chamber. Upon passage of vaporous material from the reaction chamber through the valve, substantially no vaporous material accumulates on surfaces of the valve.

The device can be structured for use with a semiconductor deposition apparatus such as a chemical vapor deposition apparatus, among others. The device can also be structured for use within a semiconductor etching apparatus such as a plasma etching apparatus, among others.

The valve body of the throttle valve defines a valve chamber in which the plug is movably disposed. The valve chamber can be structured for laminar flow for reduced resistance to flow of vaporous by-products therethrough. The throttle valve further comprises a valve inlet, a valve outlet, and a throttle valve aperture to the valve chamber. The plug can moved into or out of a sealing engagement with the valve inlet or outlet to allow passage of vaporous material through the valve chamber.

The plug is shaped to reduce resistance to flow of the vaporous material through the valve chamber. For example, the plug can have an elliptical, a spherical, a conical, or a double-ended conical shape. The plug can comprise one or a plurality of magnets. If desired, the pressure-regulating device can include a base frame and/or a cradle to support the plug within the valve.

The actuator can comprise a motor assembly, a pneumatic assembly, a hydraulic cylinder, or an electrical solenoid, for example. A motor assembly can include a motor, a carrier, a support, and a lead screw. A pneumatic assembly can comprise a pneumatic valve, a carrier, and a support with the pneumatic valve including a valve body, a piston, and air apertures. A hydraulic cylinder assembly can comprise a carrier, a support, a cylinder body, a piston, and a hydraulic conduit. An electrical solenoid can include a carrier, a support, a solenoid body, a shaft, and an electrical line.

In another embodiment, the pressure-regulating device used with the reaction chamber can comprise a valve having a valve aperture, a plug comprising a plug magnet disposed within the valve, a ring magnet surrounding the valve, and a selectively actuatable power source associated with the ring magnet, for example, a variable power source wherein the ring magnet functions as an electromagnet. The ring magnet is magnetically associated with the plug magnet and the power source is operable to magnetically bias the plug magnet and move the plug into or out of a sealing engagement with the valve aperture to regulate pressure within the reaction chamber.

The pressure-regulating device can be employed, for example, within a chemical vapor deposition apparatus or an etching apparatus. Therefore, in another aspect, the invention provides a semiconductor deposition apparatus comprising a reaction chamber and the pressure-regulating valve device. The reaction chamber is structured for receiving reaction source gases and comprises an outlet for expelling vaporous by-product. The valve device is connected to the outlet of the reaction chamber for passage of the by-product therethrough.

The apparatus can employ an exhaust pump that operates to draw the vaporous by-product from the reaction chamber toward the valve device. The apparatus can additionally comprise a thermal energy source, such as a heating coil, to heat the reaction chamber. Also, the apparatus can include a flow meter to monitor flow of the gases into the reaction chamber and a flow valve to regulate flow of the gases into the reaction chamber. Further, the apparatus includes a gas inlet pipe and an outlet pipe connected for passage of vaporous material from the reaction chamber.

In another aspect, the invention provides a method of regulating pressure in the reaction chamber of the vapor deposition apparatus. The method comprises providing the reaction chamber and the valve device and allowing fluid communication therebetween. Thereafter, gas introduced into the reaction chamber is allowed to react. The magnet is moved along the throttle valve by activating the actuator such that the plug is moved within the valve chamber into or out of a sealing engagement with the valve aperture to regulate passage of vaporous by-product from the reaction chamber through the valve chamber. Therefore, the pressure within the reaction chamber can be regulated. Use of the throttle valve according to the invention results in substantially no vaporous by-product accumulating on exposed surfaces of the throttle valve.

Depending on the actuator selected, for example, a motor assembly or a pneumatic assembly, the method can further comprise energizing a motor to rotate a lead screw or introducing air into or releasing air from an air aperture to expand or retract a piston, respectively. Alternatively, the method can further comprise actuating a power source associated with the magnet to produce an electro-magnet. In each case, the plug can be moved within the valve chamber and into or out of a sealing engagement with the valve aperture to regulate passage of vaporous by-product from the reaction chamber through the valve chamber, and regulate pressure within the reaction chamber.

### BRIEF DESCRIPTION OF THE DRAWINGS

Embodiments of the invention are disclosed with reference to the accompanying drawings and are for illustrative purposes only. The invention is not limited in its application to the details of construction, or the arrangement of the components, illustrated in the drawings. The invention is capable of other embodiments or of being practiced or carried out in other various ways. Like reference numerals are used to indicate like components.

FIG. 1 illustrates a schematic, side view of a conventional chemical vapor deposition apparatus as known in the art.

FIG. 2 illustrates a top, cross-sectional view of an embodiment of a magnetically-actuatable throttle valve according to the invention, employing a motor assembly and in a closed position.

FIG. 2A illustrates a top, cross-sectional view of the magnetically-actuatable throttle valve of FIG. 2 in an open position.

FIG. 2B illustrates a cross-sectional view of the magnetically-actuatable throttle valve of FIG. 2 taken along line 2B-2B.

FIG. 3 illustrates a top, cross-sectional view of another embodiment of a magnetically-actuatable throttle valve, according to the invention, employing a pneumatic assembly and in an open position.

FIG. 3A illustrates a portion of the throttle valve from FIG. 3 with a hydraulic cylinder assembly replacing the pneumatic assembly.

FIG. 3B. illustrates a portion of the throttle valve from FIG. 3 with an electrical solenoid assembly replacing the pneumatic assembly.

FIG. 4 illustrates a top, cross-sectional view of the magnetically-actuatable throttle valve of FIG. 3 in a closed position.

FIG. 5 illustrates a top, cross-sectional view of the magnetically-actuatable throttle valve of FIG. 3 employing a stabilizing base frame and in an opened position.

FIG. 5A illustrates a side elevational, cross-sectional view of the magnetically-actuatable throttle valve and stabilizing base frame of FIG. 5 taken along line 5A-5A.

FIG. 6 illustrates a top, cross-sectional view of another embodiment of a magnetically-actuatable throttle valve, according to the invention, employing an electromagnet and in a closed position.

FIG. 7 illustrates a top, cross-sectional view of the magnetically-actuatable throttle valve of FIG. 6 in an opened position.

FIG. 8 illustrates a top, cross-sectional view of the magnetically-actuatable throttle valve of FIG. 6 in an intermediate position.

FIG. 9 illustrates a top, cross-sectional view of another embodiment of a magnetically-actuatable throttle valve according to the invention, employing a plug comprising a plurality of plug magnets.

### DETAILED DESCRIPTION OF THE PREFERRED EMBODIMENTS

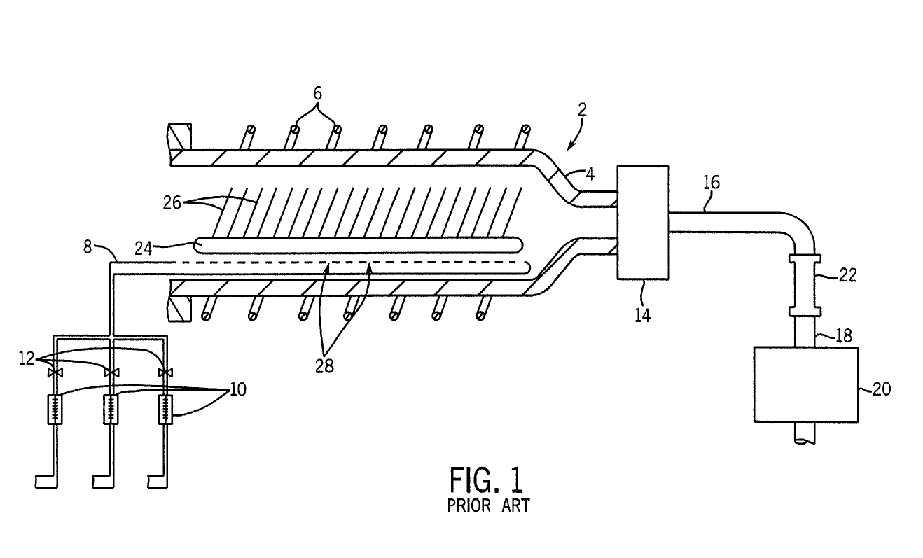

The invention will be described generally with reference to the drawings for the purpose of illustrating embodiments only and not for purposes of limiting the same. Referring to FIG. 1, a conventional chemical vapor deposition (CVD) apparatus 2, as known in the art, is schematically illustrated. Various components can be included within CVD apparatus 2, such as reaction chamber 4, thermal energy source 6, inlet pipe 8, flow meters 10, flow valves 12, connector 14, outlet pipe 16, downstream outlet pipe 18, exhaust pump 20, and pressure control mechanism 22.

Reaction chamber 4 can provide a temporary storage area for cassette 24 (i.e., boat, tray, etc.) which can carry, store, and/or transport semiconductor substrates 26. Semiconductor substrates 26 refer to any supporting structure and can include, but are not limited to, semiconductor wafer fragments or wafers.

One or more gases can be introduced into reaction chamber 4 through inlet pipe 8 and released into the reaction chamber through one or more inlet openings 28. Once released, the gases can be mixed and/or reacted within reaction chamber 4 according to known CVD processing techniques to deposit a film (not shown) on the surfaces of substrates 26. The film can comprise a semiconductor material such as polysilicon, among others; a dielectric such as silicon nitride, silicon dioxide, and titanium nitride, among others; or a conductor such as tungsten, titanium, and aluminum, among others.

One or more flow meters 10 and one or more flow valves 12 can be disposed within inlet pipe 8 to monitor, control, and/or regulate flow (i.e., egress) of the gas into reaction chamber 4. Flow valves 12 are designed and configured to regulate gas flow through inlet pipe 8. Further, flow meters 10 are designed and configured to monitor the rate and/or volume of the gas flow through inlet pipe 8. When working in combination, flow meters 10 and flow valves 12 permit the monitoring and/or regulation of the gas flow into reaction vessel 4.

An energy source, typically a thermal energy source, drives the film forming reactions. In the illustrated embodiment, thermal energy source 6 comprises helical heating coils that circumferentially, longitudinally surround reaction chamber 4.

Eventually, by-products (e.g., un-reacted gases, vaporous materials) of the reaction gases are discharged from reaction chamber 4. As illustrated, the by-products are expelled from reaction chamber 4 through connector 14 into outlet pipe 16. Exhaust pump 20 (i.e., vacuum pump), as schematically illustrated in FIG. 1, can control discharge of the by-product flow from reaction chamber 4. After leaving reaction chamber 4 and entering outlet pipe 16, the by-products flow through pressure control mechanism 22 which is typically employed within CVD apparatus 2 to regulate pressure within reaction chamber 4. Conventional pressure control mechanisms 22 include a valve, a throttle valve, a vacuum valve, a butterfly valve, and the like. Unfortunately, such valves all too often experience undesirable adduct accumulation from the deposition of reaction by-products on the mechanical and/or structural components and/or assemblies, particularly in trap areas and/or in tight tolerance areas. As adduct accumulates within pressure control mechanism 22, the mechanism can become inefficient, require an inordinate amount of maintenance, and/or fail to function.

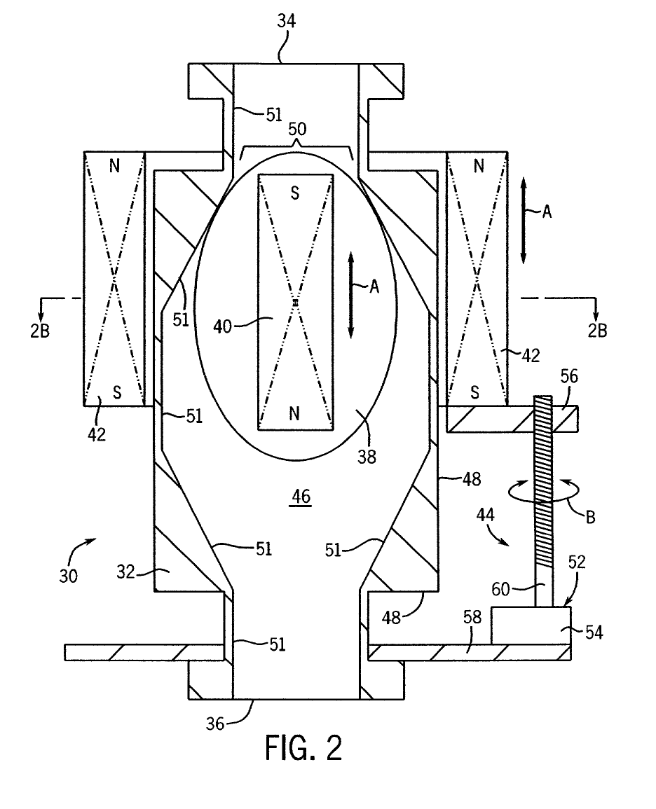

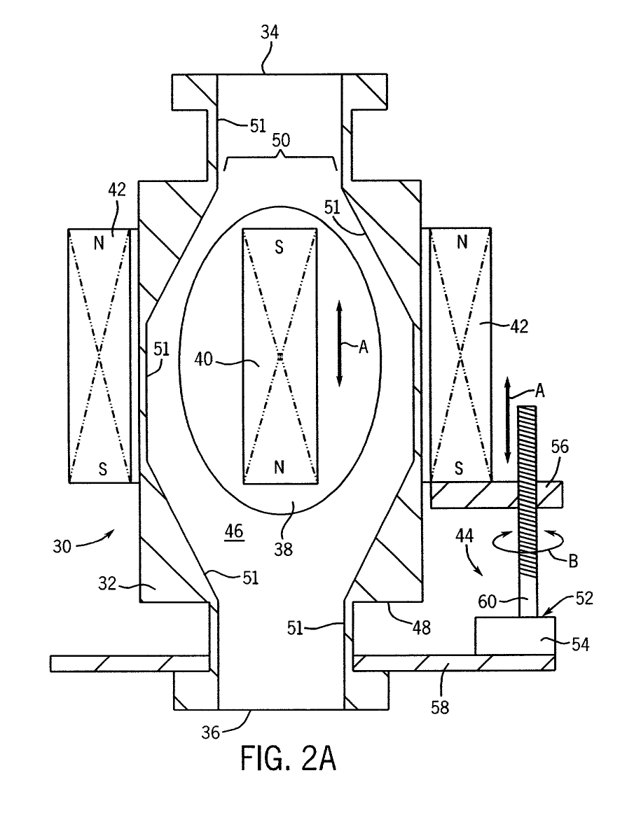

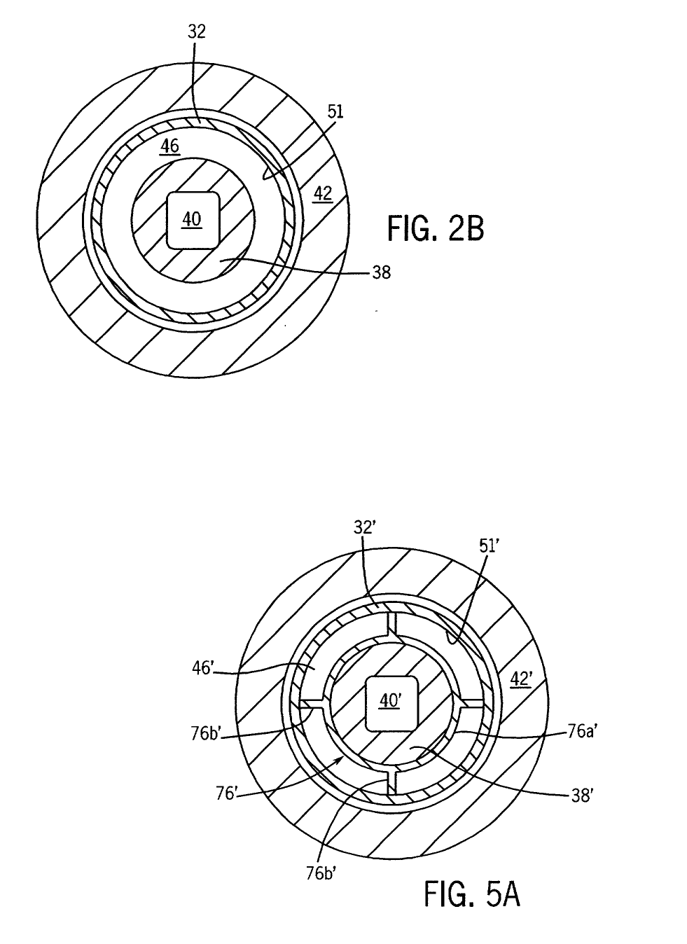

In FIG. 2, an embodiment of magnetically-actuatable throttle valve 30, according to the invention, is illustrated. Magnetically-actuatable throttle valve 30 is designed, configured, and/or intended to replace pressure control mechanism 22 in CVD apparatus 2. When magnetically-actuatable throttle valve 30 is used, accumulation of adduct is substantially reduced compared to conventional pressure control mechanisms such as a vacuum throttle valve. As shown in FIGS. 2-8, magnetically-actuatable valve 30 comprises valve body 32, valve inlet 34, valve outlet 36, plug 38, plug magnet 40, ring magnet 42, and actuator 44.

Valve body 32 defines valve chamber 46, valve exterior 48, and valve aperture 50. Valve body 32 can be fabricated from a variety of materials that are resistant to reaction with the by-product materials. Exemplary materials for valve body 32 include stainless steel, aluminum, among others. Valve body 32 can be fabricated by known manufacturing processes, including, for example, conventional machining or a molding process such as injection molding, extrusion, compression molding, among other methods.

Valve chamber 46 is designed and configured to selectively permit the reaction by-products to flow therethrough. In preferred embodiments, valve chamber 46 promotes laminar flow and, as such, reduces resistance to any gas, fluid, or reaction by-product material passing through the valve chamber. This inhibits the deposition and accumulation of by-product material on walls or surfaces 51 of valve chamber 46 and valve body 32 and thereby eliminates adduct build-up. As illustrated in FIGS. 2-8, valve inlet 34 can be disposed at one end of valve body 32 while valve outlet 36 can be disposed at another end of the valve body. Valve inlet 34 and valve outlet 36 can comprise, in preferred embodiments, threaded members to attach or connect in a mating fashion to other various threaded components. While valve inlet 34 and valve outlet 36 are described as threaded, and arranged at opposing ends of valve body 32 in FIGS. 2-8, these arrangements are not required and further known arrangements known to those skilled in the art are contemplated.

When magnetically-actuatable throttle valve 30 (e.g., as shown in FIG. 2) replaces pressure control mechanism 22 in CVD apparatus 2 as schematically shown in FIG. 1, valve inlet 34 is secured to outlet pipe 16 and valve outlet 36 is secured to downstream outlet pipe 18. When permitted, the reaction by-products can flow and/or proceed through magnetically-actuatable throttle valve 30 by entering at valve inlet 34 and thereafter passing through valve chamber 46. The by-products can subsequently be discharged from magnetically-actuatable throttle valve 30 at valve outlet 36.

In contrast to the manner in which conventional pressure control mechanisms 22 control the flow of the reaction by-products, the flow of the reaction by-products through magnetically-actuatable throttle valve 30 can be controlled by magnetically actuating plug 38.

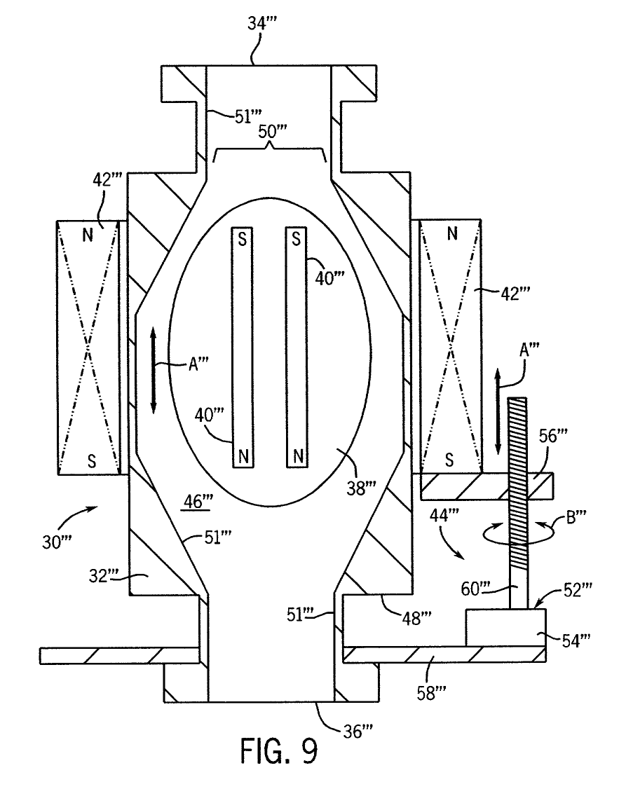

Plug 38, as illustrated in FIGS. 2-9, houses plug magnet 40. Therefore, any force and/or bias exerted upon plug magnet 40 can be directly translated to plug 38. The polarity of plug magnet 40 is indicated with an “N” and an “S” on the plug magnet in each of the drawing Figures and the orientation of the polarity (N-S) can be reversed as desired. Further, although FIG. 2 depicts plug magnet 40 as a single magnet, the plug magnet can comprise a series and/or a plurality of individual magnets 40′″, for example, as shown in FIG. 9. Plug 38 is generally disposed within valve body 32, and in particular, within valve chamber 46. As shown, plug 12 is not mechanically, structurally, or otherwise directly connected to valve body 32 or actuator 44. In other words, plug 38 is “free floating” in the chamber. Thus, no mechanically or structurally accommodating and/or corresponding slots, grooves, recesses, detents, protrusions, or the like need to be machined or exist upon, or within, valve body 32, valve chamber 46, and/or magnetically-actuatable throttle valve 30. Thus, adduct is not provided a convenient place or locale to deposit, attach, or accumulate.

Plug 38 can be in the form of a variety of geometric and other shapes. In preferred embodiments, plug 38 comprises an aerodynamic, laminar-promoting, and/or turbulence-reducing shape. Plug 38 can comprise an ellipsoid, a sphere, a cone, a double-ended cone, and the like, such that the plug has a cross-section (FIG. 2B) that resembles, for example, an ellipse, a circle, a triangle, a diamond, and the like. In the illustrated example in FIGS. 2-2B, plug 38 is an elliptical shape and circular in cross section. Within valve chamber 46, plug 38 is capable of moving longitudinally, shifting back and forth, moving toward or away from valve inlet 34, moving toward or away from valve outlet 36 and/or being generally actuated in at least one direction.

Plug 38 can be fabricated from a variety of materials that are resistant to reaction with the by-product materials. Exemplary materials for forming plug 38 include tetrafluoroethylene (Teflon™), stainless steel, among others. Plug 38 can be fabricated by known manufacturing processes, including, for example, a molding process such as injection molding, extrusion, compression molding, among other methods. Plug magnet 40 can be disposed (i.e., inserted, placed, etc.) within plug 38 by encapsulation and/or mechanical capture.

As shown in FIG. 2, ring magnet 42, in preferred embodiments, can be a cylindrical or tubular magnet that is externally disposed about valve body 32. For example, a tubular ring magnet 42 can be slipped over or wrapped around valve body 32. Although ring magnet 42 is illustrated and described as being cylindrical or tubular, the ring magnet is not limited to these configurations. It is contemplated that ring magnet 42 can comprise a variety of shapes and/or designs. Orientation of the polarity of ring magnet 42, indicated with an “N” and an “S” in each of the drawing figures, can be reversed to coincide with the orientation of the plug magnet 40.

Actuator 44 can be secured to valve body 32 and can comprise various mechanisms for providing movement of ring magnet 42. It is contemplated that actuator 44 can comprise a motor assembly, a pneumatic assembly, an electrical solenoid, a hydraulic cylinder, or other actuating mechanism capable of providing linear motion. In the embodiment illustrated in FIG. 2, actuator 44 comprises a motor assembly 52. Motor assembly 52 can include motor 54, carrier 56, support 58, and lead screw 60. Motor 54 can include a variety of conventional motors such as a drive motor, a stepper motor, an electric motor, an electric direct current (DC) motor, and the like.

As illustrated in FIG. 2, ring magnet 42 is secured to carrier 56 of motor assembly 52, and the carrier is secured to, and associated with, lead screw 60. Continuing, lead screw 60 is secured to, and associated with, motor 52 and the motor is secured to support 58. As lead screw 60 alternatively rotates either clockwise or counter-clockwise (directional arrow B), the lead screw can push or pull carrier 56 toward, or away from, motor 52 (directional arrow A). Therefore, ring magnet 42 is capable of moving along and/or about valve body 32. In other words, ring magnet 42 translates longitudinally back and forth along valve body 32 (directional arrow A). As this occurs, ring magnet 42 and plug magnet 40 magnetically interact. The magnetic interaction permits plug 38 to be moved toward, or away, from valve inlet 34 within valve chamber 46 as shown by directional arrow A in FIGS. 2-10.

Because magnetically-actuatable throttle valve 30 uses the magnetic interaction between ring magnet 42 and plug magnet 40 to move plug 38, there are no surfaces (e.g., such as those formed by mechanical and/or structural components and/or assemblies) onto which reaction by-products are inclined to accumulate or deposit within the magnetically-actuatable throttle valve. Further, the magnetic interaction between ring magnet 42 and plug magnet 40, in combination with the use of a smooth-walled and stream-lined valve chamber 46, permit magnetically-actuatable throttle valve 30 to be free of moving mechanically-connected parts, sliding structurally-connected parts, trap areas, and/or tight tolerance areas. Also, magnetically-actuatable throttle valve 30 is not subject to excessive maintenance, does not contribute to poor exhaust pump 20 performance (FIG. 1), and does not cause downtime for a CVD apparatus 2 such as that illustrated in FIG. 1.

In FIG. 2, plug 38 within magnetically-actuatable throttle valve 30, which is employing motor assembly 52, is engaged with valve aperture 50. Thus, magnetically-actuatable throttle valve 30 is in the “closed” position. The reaction by-products are restricted from flowing through valve inlet 34 into chamber 46. In FIG. 2A, plug 38 within magnetically-actuatable throttle valve 30 is disengaged from valve aperture 50. Thus, magnetically-actuatable throttle valve 30 is in the “open” position. The reaction by-products are permitted to flow through valve inlet 34 and valve chamber 46, and out valve outlet 36.

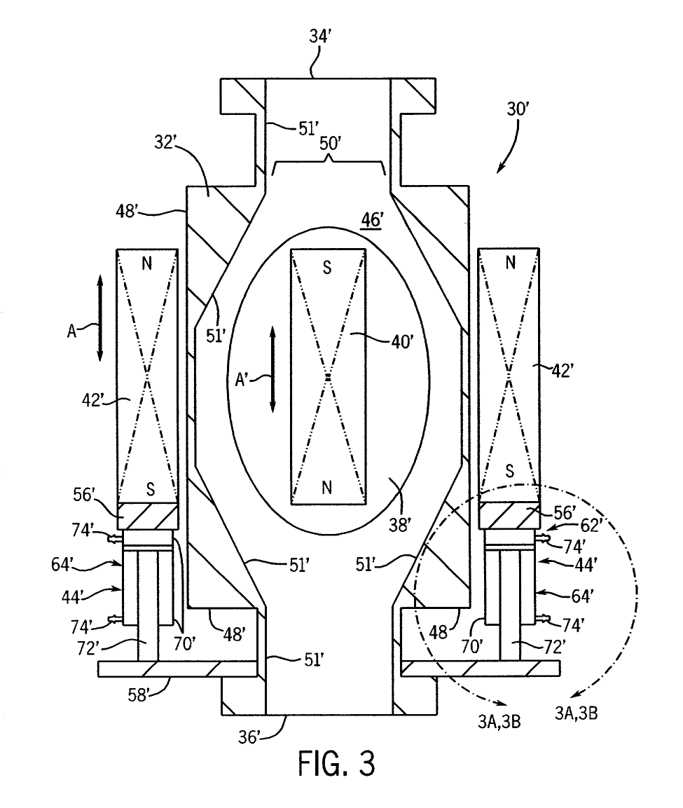

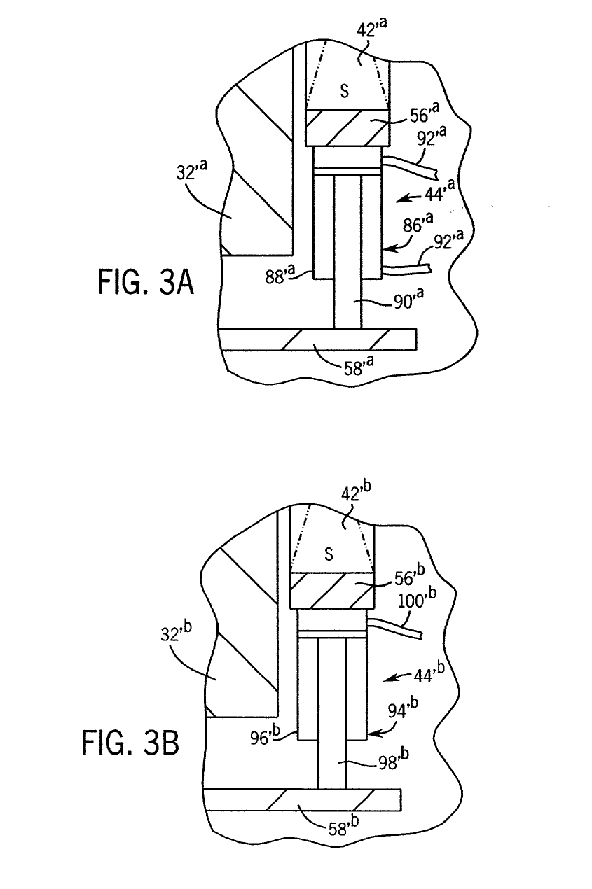

In another embodiment of a magnetically-actuatable throttle valve 30′ according to the invention, as depicted in FIG. 3, actuator 44′ comprises pneumatic assembly 62′. As shown, pneumatic assembly 62′ includes pneumatic valve 64′, carrier 56′, and support 58′. Pneumatic valve 64′ can comprise pneumatic valve body 70′, piston 72′, and at least one air aperture 74′. As illustrated in FIG. 3, ring magnet 42′ is secured to carrier 56′ and the carrier is secured to pneumatic valve body 70′. Continuing, pneumatic valve body 70′ is secured to, and associated with, piston 72′ and the piston is secured to support 58′.

As illustrated in FIG. 3, in a preferred embodiment, each pneumatic valve 64′ comprises two air apertures 74′. As air (or some other gas and/or a liquid) is alternatively and/or intermittently introduced or released from air apertures 74′, piston 72′ can extend or retract toward, or away from support 58′ as shown by directional arrow A. Therefore, piston 72′ can thrust carrier 56′ toward, or away from, support 58′ which permits ring magnet 42′ to translate longitudinally back and forth along valve body 32′ as shown by directional arrow A. Ring magnet 42′ is once again capable of moving along and/or about valve body 32′ (directional arrow A). As this occurs, ring magnet 42′ magnetically biases plug magnet 40′ such that plug 38′ resultantly moves longitudinally within valve chamber 46′ (directional arrow A).

In another embodiment of a magnetically-actuatable throttle valve 30′^{a} according to the invention, as depicted in FIG. 3A, a hydraulic cylinder assembly 86′^{a} replaces pneumatic valve assembly 62′ from FIG. 3. Hydraulic cylinder assembly 86′^{a} can comprise carrier 56′^{a}, support 58′^{a}, cylinder body 88′^{a}, piston 90′^{a}, and at least one hydraulic conduit 92′^{a}. As illustrated in FIG. 3A, ring magnet 42′^{a} is secured to carrier 56′^{a} and the carrier is secured to cylinder body 88′^{a}. Continuing, cylinder body 88′^{a} is secured to, and associated with, piston 90′^{a} and the piston is secured to support 5840 ^{a}. As hydraulic conduits 92′^{a} selectively provide hydraulic fluid to hydraulic cylinder 86′^{a}, piston 90′^{a} retracts or expands to move ring magnet 42′^{a} along and/or about valve body 32′^{a}. As this occurs, the ring magnet 42′^{a} magnetically biases the plug magnet (not shown) such that the plug (not shown) resultantly moves longitudinally within the valve chamber 46′^{a}.

In yet another embodiment of a magnetically-actuatable throttle valve 30′^{b} according to the invention, as depicted in FIG. 3B, an electrical solenoid assembly 94′^{b} replaces pneumatic valve assembly 62′ from FIG. 3. Electrical solenoid assembly 94′^{b} can comprise carrier 56′^{b}, support 58′^{b}, solenoid body 96′^{b}, shaft 98′^{b}, and electric line 100′^{b}. As illustrated in FIG. 3B, ring magnet 42′^{b} is secured to carrier 56′^{b} and the carrier is secured to solenoid body 96′^{b}. Continuing, solenoid body 96′^{b} is secured to, and associated with, shaft 98′^{b} and the piston is secured to support 58′^{b}. As electric line 100′^{b} selectively provides power to electrical solenoid 94′^{b}, shaft 98′^{b} retracts or expands to move ring magnet 42′^{b} along and/or about valve body 32′^{b}. As this occurs, the ring magnet 42′^{b} magnetically biases the plug magnet (not shown) such that the plug (not shown) resultantly moves longitudinally within the valve chamber 46′^{b}.

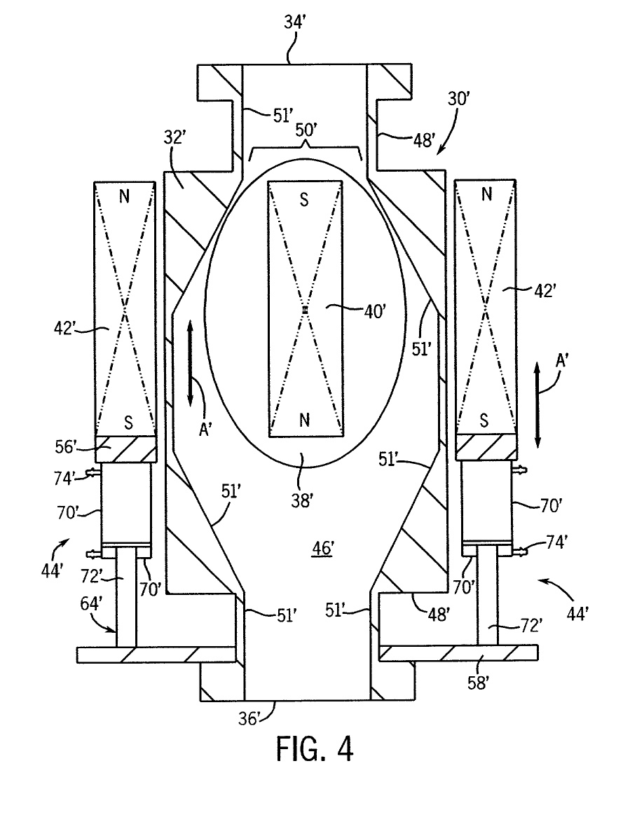

In FIG. 3, plug 38′ within magnetically-actuatable throttle valve 30′, which is employing pneumatic assembly 62′, is disengaged from valve aperture 50′. Thus, magnetically-actuatable throttle valve 30′ is in the “open” position. The reaction by-products are permitted to flow through valve inlet 34′, valve chamber 46′, and valve outlet 36′. In FIG. 4, plug 38′ within magnetically-actuatable throttle valve 30′ is engaged with valve aperture 50′. Thus, magnetically-actuatable throttle valve 30′ is in the “closed” position. The reaction by-products are restricted from flowing through valve inlet 34′.

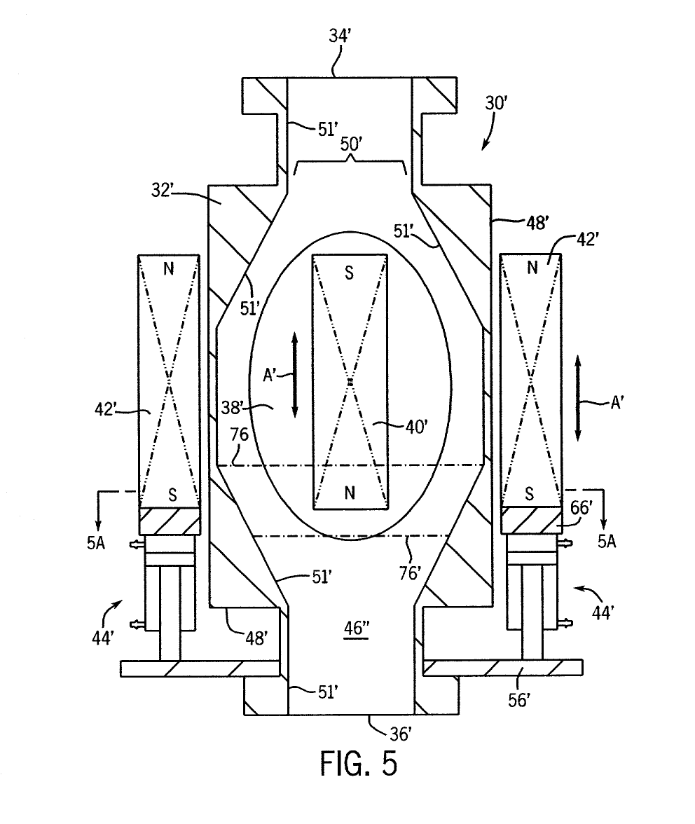

Optionally, as shown in FIGS. 5 and 5A, magnetically-actuatable throttle valve 30′ can include stabilizing base frame 76′. Stabilizing base frame 76′ is structured for receiving and/or securing plug 38′ during operation and/or use of actuator 44′, particularly when the actuator is represented by pneumatic assembly 62′.

Stabilizing base frame 76′ comprises support ring 76a′ and support arm 76b′ and can be fabricated from a variety of materials that are resistant to reaction with the by-product materials. Exemplary materials for forming base frame 76′ include tetrafluoroethylene (Teflon™), stainless steel, aluminum, among others. Base frame 76′ can be fabricated by known manufacturing processes, including, for example, machining, casting, mechanical assembly of parts, among other methods. Base frame 76′ can be disposed within valve body 32′ by press fit, mechanical capture, welding, among other methods.

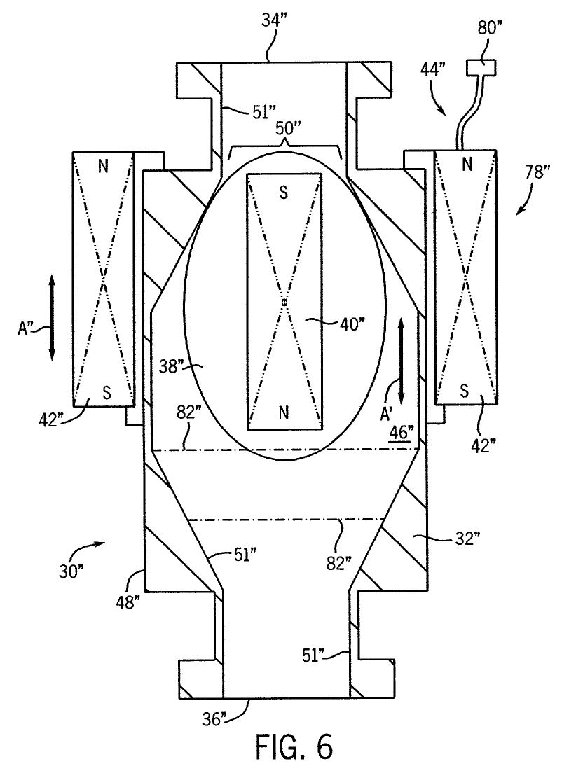

In another embodiment of a magnetically-actuatable throttle valve 30″, according to the invention, as depicted in FIG. 6, ring magnet 42″ is in the form of an electromagnet 78″ which is associated with a power source 80″. Power source 80″ can comprise a variable voltage power source such as a DC power source, an AC power source, and the like, as conventionally known as used in the art. When electromagnet 78″ is alternatively and/or intermittently energized by power source 80″, the electromagnet magnetically biases plug magnet 40″ such that plug 38″ resultantly moves longitudinally within valve chamber 46″ (directional arrow A). Optionally, as shown in FIGS. 6-8, cradle 82″ can be employed within valve chamber 46″ to receive and/or secure plug 38″ during operation. Cradle 82″ can be structured substantially similar to stabilizing base frame 76′ as illustrated in FIG. 5A.

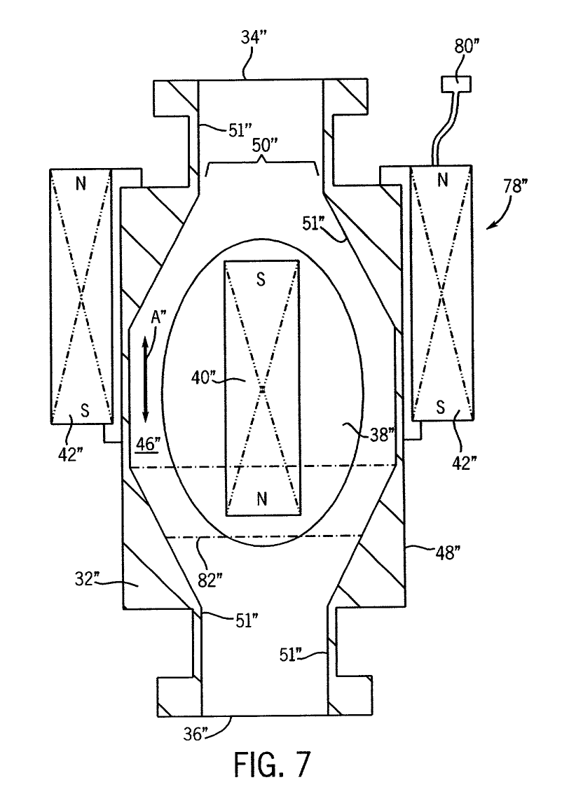

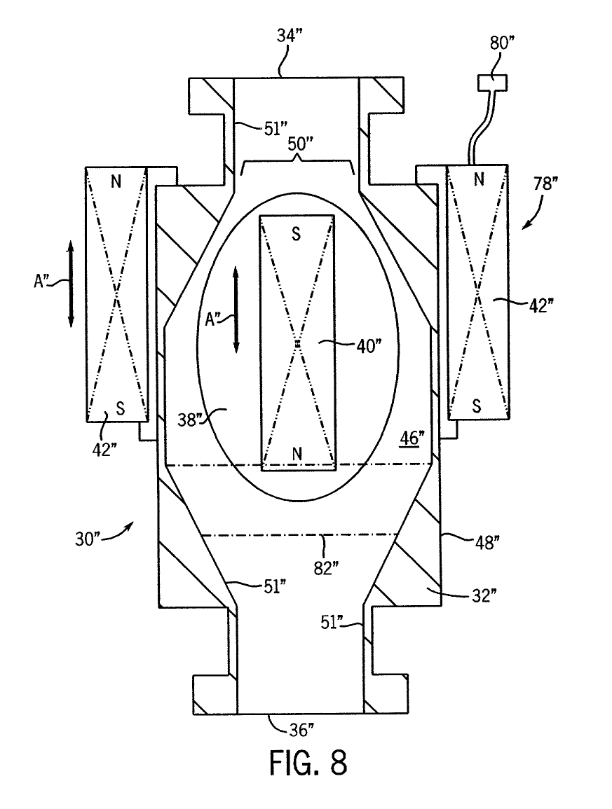

In FIG. 6, plug 38″ within magnetically-actuatable throttle valve 30″, employing electro-magnet 78″, is engaged with valve aperture 50″. Thus, magnetically-actuatable throttle valve 30″ is in the “closed” position. The reaction by-products are restricted from flowing through valve inlet 34″. In FIG. 7, plug 38″ within throttle valve 30″ is disengaged from valve aperture 50″. Thus, magnetically-actuatable throttle valve 30″ is in the “open” position. The reaction by-products are permitted to flow through valve inlet 34″, valve chamber 46″, and valve outlet 36″. In FIG. 8, plug 38″ is “intermediately” disengaged from valve aperture 50″. Thus, magnetically-actuatable throttle valve 30″ is in an a “partially open” or “intermediate” position. While the reaction by-products are permitted to flow into valve chamber 46″ within throttle valve 30″ in the partially open position, the flow of by-products into the valve chamber is reduced, but not completely prohibited. The partially opened position allows plug 38″ to be disposed at any position between the opened position (FIG. 7) and the closed position (FIG. 6). Although perhaps slowed, the reaction by-products are nonetheless permitted to flow through valve inlet 34″, valve chamber 46″, and valve outlet 36″ when valve 30″ is in a partially opened position.

Referring for example to FIG. 2, as magnetically-actuatable throttle valve 30, is operated, plug 38 can move within valve chamber 46 between the open position and the closed position, and preferably, to any position between the opened and closed positions. When the closed position is experienced, plug 38 maintains a sealing engagement with valve aperture 50 (e.g., FIGS. 2, 4 and 6). To form the sealing engagement, plug 38 can be urged toward valve inlet 34 by actuator 44. When plug 38 has traveled far enough, the plug encounters, abuts, and/or enters valve aperture 50 to form, in preferred embodiments, a gas-impermeable (i.e., liquid-impermeable, fluid-impermeable, etc.) seal. To encourage the sealing engagement, and the formation of the seal, in preferred embodiments valve aperture 50 is elliptical, round, or otherwise configured to correspond to the shape of plug 38. Thus, plug 38 can prohibit the reaction by-products from entering valve chamber 46.

Plug 38 can also be urged toward valve outlet 36 by actuator 44. When plug 38 terminates contact with valve aperture 50 (e.g., FIGS. 2A, 3, 5, and 7-9), the reaction by-products can begin to flow through valve chamber 46. In exemplary embodiments, the rate of flow and/or egress of the reaction by-products can be controlled by actuating plug 38 within valve chamber 46 (e.g., when magnetically-actuatable throttle valve 30 is in the partially opened position). Referring to FIG. 8, electro-magnet power source 80″ of electro-magnet 78″ can comprise a variable voltage power source to better achieve positioning of plug 38″ relative to valve outlet 36″ so that the valve is in a partially opened position. Thus, by using variable voltage, electro-magnet 78″ can perform as a “voice coil driver”, as is known in the art, to obtain modulation of the position of the plug within the vacuum passage. Depending how far plug 38 is drawn away from the sealing engagement with valve aperture 50, the rate of flow and/or egress of the reaction by-products can be permitted to increase and decrease.

Among other advantages, magnetically-actuatable throttle valve 30 eliminates mechanical motion “feedthroughs”, that is apertures through valve body 32 that accommodate mechanical assemblies and/or components, and, therefore, inhibits leaking from within valve chamber 46 (e.g., vacuum leaks). Further, throttle valve 30 contains only one moving part, plug magnet 40, within valve chamber 46, as opposed to numerous moving parts found in conventional valves. Also, throttle valve 30 permits rapid actuation of plug 38 due to the absence of mechanical assemblies and associated apertures found in conventional valves. Rate of actuation of plug 38, for the most part, corresponds directly to the speed of the actuator utilized (or electromagnet 78″ where utilized). Thus, the faster the actuator 44 selected for valve 30, the faster plug 38 can be moved within chamber 46. For example, when the throttle valve employs an electromagnet 78″ or pneumatic assembly 62′, actuation of the plug from an “opened” position to a “closed” position can be performed in tens of milliseconds.

It is contemplated, and can be appreciated in the art, that particular embodiments of actuator 44 within magnetically-actuatable valve 30 can be more favorably suited for two-position actuation (e.g., either an opened or closed position) while other embodiments can be more favorably suited for variable and/or modulating positions (e.g., an open or closed position as well as a variety of positions in between the opened and closed positions).

In addition to CVD apparatus 2 as illustrated in FIG. 1, the magnetically-actuatable valve of the invention can be employed within other CVD apparatuses including, but not limited to, atomic layer deposition (ALD), physical vapor deposition (PVD), atomic layer epitaxy (ALE), plasma-enhanced CVD (PECVD), low-pressure CVD (LPCVD), metallic-organic CVD (MOCVD), and the like. Also, magnetically-actuatable valve 30 can be employed within dry etching apparatuses including, but not limited to, plasma etching, high-density plasma etching, microwave etching, reactive ion etching (REI), and the like.

Despite any methods being outlined in a step-by-step sequence, the completion of acts or steps in a particular chronological order is not mandatory. Further, elimination, modification, rearrangement, combination, reordering, or the like, of acts or steps is contemplated and considered within the scope of the description and claims.

While the present invention has been described in terms of the preferred embodiment, it is recognized that equivalents, alternatives, and modifications, aside from those expressly stated, are possible and within the scope of the appending claims.

What is claimed is:

1. A pressure-regulating device for use with a reaction chamber, the device comprising:
a valve having a valve aperture;
a plug disposed within the valve;
a plug magnet disposed within the plug;
a ring magnet surrounding the valve, the ring magnet magnetically associated with the plug magnet; and
an actuator associated with the valve, the actuator operable to move the ring magnet along the valve and magnetically bias the plug magnet to move the plug into or out of a sealing engagement with the valve aperture to regulate pressure within the reaction chamber;
whereby, upon passage of vaporous material from the reaction chamber through the valve, substantially no vaporous material accumulates on surfaces of the valve.

2. The device of claim 1, structured for use with a semiconductor deposition apparatus, the semiconductor deposition apparatus selected from the group consisting of a chemical vapor deposition apparatus, an atomic layer deposition apparatus, a physical vapor deposition apparatus, an atomic layer epitaxy apparatus, a plasma-enhanced chemical vapor deposition apparatus, a low-pressure chemical vapor deposition apparatus, and a metallic-organic chemical vapor deposition apparatus.

3. The device of claim 1, structured for use within a semiconductor etching apparatus selected from the group consisting of a dry etching apparatus, a plasma etching apparatus, a high-density plasma etching apparatus, a microwave etching apparatus, and a reactive ion etching apparatus.

4. The device of claim 1, wherein the plug is aerodynamically shaped.

5. The device of claim 1, wherein the plug is configured to reduce resistance to flow of the vaporous material.

6. The device of claim 1, wherein the plug is structured for laminar flow of the vaporous material through the valve.

7. The device of claim 1, wherein the plug comprises an elliptical, a spherical, a conical, or a double-ended conical shape.

8. The device of claim 1, wherein the plug is movable toward or away from the valve aperture.

9. The device of claim 1, wherein the plug is movable longitudinally within the valve.

10. The device of claim 1, wherein the valve aperture comprises a round or elliptical opening.

11. The device of claim 1, wherein the plug magnet comprises a plurality of magnets.

12. The device of claim 1, wherein the ring magnet comprises a cylindrical or a tubular shape.

13. The device of claim 1, wherein the actuator is selected from the group consisting of a motor assembly, a pneumatic assembly, a hydraulic cylinder, and an electrical solenoid.

14. The device of claim 13, wherein the motor assembly comprises a motor, a carrier, a support, and a lead screw.

15. The device of claim 13, wherein the pneumatic assembly comprises a pneumatic valve, a carrier, and a support, the pneumatic valve having a valve body, a piston, and at least one air aperture.

16. The device of claim 1, further comprising a base frame to support the plug within the valve.

17. The device of claim 1, further comprising a cradle to support the plug within the valve.

18. A pressure-regulating device for use with a reaction chamber, the device comprising:
a valve having a valve aperture;
a plug disposed within the valve;
a plug magnet disposed within the plug;
a magnet surrounding the valve, the magnet magnetically associated with the plug magnet; and
a motor assembly connected to the valve, the motor assembly operable to move the magnet along the valve and magnetically bias the plug magnet to move the plug into or out of a sealing engagement with the valve aperture to regulate pressure within the reaction chamber;
whereby, upon passage of vaporous material from the reaction chamber through the valve, substantially no vaporous material accumulates on surfaces of the valve.

19. The device of claim 18, wherein the motor assembly comprises a motor, a carrier, a support, and a lead screw.

20. A pressure-regulating device for use with a reaction chamber, the device comprising:
a valve having a valve aperture;
a plug disposed within the valve;
a plug magnet disposed within the plug;
a magnet surrounding the valve and magnetically associated with the plug magnet; and
a pneumatic assembly connected to the valve, the pneumatic assembly operable to move the magnet along the valve and magnetically bias the plug magnet to move the plug into or out of a sealing engagement with the valve aperture to regulate pressure within the reaction chamber;
whereby, upon passage of vaporous material from the reaction chamber through the valve, substantially no vaporous material accumulates on surfaces of the valve.

21. The device of claim 20, wherein the pneumatic assembly comprises a pneumatic valve, a carrier, and a support, the pneumatic valve having a valve body, a piston, and at least one air aperture.

22. A pressure-regulating device for use with a reaction chamber, the device comprising:
a valve having a valve aperture;
a plug disposed within the valve;
a plug magnet disposed within the plug;
a ring magnet surrounding the valve, the ring magnet magnetically associated with the plug magnet; and
a selectively actuatable power source associated with the ring magnet, the power source operable to magnetically bias the plug magnet to move the plug into or out of a sealing engagement with the valve aperture to regulate pressure within the reaction chamber;
whereby, upon passage of vaporous material from the reaction chamber through the valve, substantially no vaporous material accumulates on surfaces of the valve.

23. The device of claim 22, wherein the power source comprises a variable voltage power source.

24. A pressure-regulating device for use with a reaction chamber in a chemical vapor deposition apparatus, the device comprising:
a throttle valve having a throttle valve aperture;
a plug within the throttle valve;
a plug magnet disposed within the plug;
a ring magnet surrounding the throttle valve, the ring magnet magnetically associated with the plug magnet; and
a selectively actuatable power source associated with the ring magnet, the power source operable to magnetically bias the plug magnet to encourage the plug into and out of a sealing engagement with the throttle valve aperture to seal and unseal the throttle valve to regulate pressure within the reaction chamber;
wherein, upon passage of vaporous material from the reaction chamber through the throttle valve, substantially no material accumulates on surfaces of the throttle valve.

25. The device of claim 24, wherein the actuator is selected from the group consisting of a motor assembly, a pneumatic assembly, a hydraulic cylinder, and an electrical solenoid.

26. A pressure-regulating device for use with a reaction chamber in a chemical vapor deposition apparatus, the device comprising:
a throttle valve having a throttle valve aperture;
a plug within the throttle valve;
a plug magnet disposed within the plug;
a ring magnet surrounding the throttle valve, the ring magnet magnetically associated with the plug magnet; and
a selectively actuatable power source associated with the ring magnet, the power source operable to magnetically bias the plug magnet to move the plug into or out of a sealing engagement with the valve aperture to regulate pressure within the reaction chamber;
wherein, upon passage of vaporous material from the reaction chamber through the throttle valve, substantially no material accumulates on surfaces of the throttle valve.

27. The device of claim 26, wherein the power source comprises a variable voltage power source.

28. A pressure-regulating device for use with a chemical vapor deposition apparatus, the pressure-regulating device comprising:
a throttle valve having a valve body defining a valve aperture and a valve chamber;
a plug movably disposed within the valve chamber;
a plug magnet disposed within the plug;
a magnet external to the valve body and magnetically associated with the plug magnet; and
an actuator connected to the valve body and the magnet, the actuator operable to move the magnet longitudinally along the valve body and thereby magnetically bias the plug magnet to move the plug toward or away from the valve aperture to open or close the valve aperture to regulate pressure within the reaction chamber of the deposition apparatus;
whereby, upon passage of vaporous by-products from the reaction chamber through the throttle valve, substantially no by-products accumulate within the throttle valve.

29. The device of claim 28, wherein the valve chamber is structured for reduced resistance to flow of vaporous by-products therethrough.

30. The device of claim 28, wherein the valve chamber is structured for laminar flow of vaporous by-products therethrough.

31. A pressure-regulating device for a chemical vapor deposition apparatus, the device comprising:
a throttle valve having a valve inlet, a valve outlet, and a valve body defining a throttle valve aperture and a valve chamber;
a plug disposed within the valve chamber, the plug movable relative to the valve inlet and the valve outlet;
a plug magnet secured to the plug;
a magnet proximate the valve body and magnetically associated with the plug magnet; and
an actuator secured to the valve body and operable to move the magnet along the valve body whereby the plug is moved into or out of a sealing engagement with the valve inlet or outlet to allow passage of vaporous material through the valve chamber; and
substantially no material accumulates within the throttle valve.

32. A semiconductor deposition apparatus comprising:
a reaction chamber for receiving one or more gases, the chamber comprising an outlet for expelling vaporous by-product from the chamber;
a valve device connected to the outlet of the reaction chamber for passage of the by-product therethrough, the valve device comprising:
a throttle valve having a valve aperture and defining a chamber;
a plug disposed within the valve chamber;
a plug magnet disposed within the plug;
a magnet disposed external to the throttle valve and magnetically associated with the plug magnet; and
an actuator connected to the magnet and operable to move the magnet to magnetically bias the plug magnet and move the plug into and out of a sealing engagement with the valve aperture to allow passage of the vaporous by-product through the valve chamber; whereby substantially no by-product accumulates on surfaces of the throttle valve.

33. The apparatus of claim 32, selected from the group consisting of a chemical vapor deposition apparatus, an atomic layer deposition apparatus, a physical vapor deposition apparatus, an atomic layer epitaxy apparatus, a plasma-enhanced chemical vapor deposition apparatus, a low-pressure chemical vapor deposition apparatus, and a metallic-organic chemical vapor deposition apparatus.

34. The apparatus of claim 32, further comprising an exhaust pump operable to draw the vaporous by-product from the reaction chamber toward the valve device.

35. The apparatus of claim 32, further comprising a thermal energy source to heat the reaction chamber.

36. The apparatus of claim 32, further comprising a flow meter to monitor flow of the one or more gases into the reaction chamber.

37. The apparatus of claim 32, further comprising a flow valve to regulate flow of the one or more gases into the reaction chamber.

38. The apparatus of claim 32, further comprising at least one of an inlet pipe connected to the reaction chamber and an outlet pipe connected for passage of vaporous material from the reaction chamber.

39. A semiconductor etching apparatus comprising:
a reaction chamber for receiving one or more gases, the chamber comprising an outlet for expelling vaporous by-product from the chamber;
a valve device connected to the outlet of the reaction chamber for passage of the by-product therethrough, the valve device comprising:
a throttle valve having a valve aperture and defining a chamber;
a plug disposed within the valve chamber;
a plug magnet disposed within the plug;
a magnet disposed external to the throttle valve and magnetically associated with the plug magnet; and
an actuator connected to the magnet and operable to move the magnet to magnetically bias the plug magnet and move the plug into and out of a sealing engagement with the valve aperture to allow passage of the vaporous by-product through the valve chamber; whereby substantially no by-product accumulates on surfaces of the throttle valve.

40. The apparatus of claim 39, selected from the group consisting of a dry etching apparatus, a plasma etching apparatus, a high-density plasma etching apparatus, a microwave etching apparatus, and a reactive ion etching apparatus.

41. A semiconductor deposition apparatus comprising:
a reaction chamber for receiving one or more gases, the chamber comprising an outlet for expelling vaporous by-product from the chamber;
a thermal energy source proximate the reaction chamber to provide heat thereto;
a valve device connected to the outlet of the reaction chamber for passage of the by-product therethrough, the valve device comprising:
a throttle valve having a valve aperture and defining a chamber;
a plug disposed within the valve chamber;
a plug magnet disposed within the plug;
a magnet disposed external to the throttle valve and magnetically associated with the plug magnet; and
an actuator connected to the magnet and operable to move the magnet to magnetically bias the plug magnet and move the plug into and out of a sealing engagement with the valve aperture to allow passage of the vaporous by-product through the valve chamber; whereby substantially no by-product accumulates on surfaces of the throttle valve.

42. The apparatus of claim 41, wherein the thermal energy source comprises a heating coil.

43. A method of regulating pressure in a reaction chamber of a vapor deposition apparatus, the method comprising the steps of:
providing the deposition apparatus, the deposition apparatus comprising the reaction chamber for receiving one or more gases therein, and a valve device in fluid communication with the reaction chamber, the valve device comprising:
a throttle valve defining a valve chamber and a valve aperture to the valve chamber;
a plug disposed within the valve chamber, the plug sealingly engageable with the valve aperture;
a plug magnet disposed within the plug;
a magnet external to the throttle valve and in magnetic association with the plug magnet; and
an actuator secured to the magnet and operable to move the magnet along the throttle valve;
introducing at least one gas into the reaction chamber and allowing the at least one gas to react;
moving the magnet along the throttle valve by activating the actuator, whereby the plug is moved within the valve chamber into or out of a sealing engagement with the valve aperture to regulate passage of vaporous by-product from the reaction chamber through the valve chamber, thereby regulating the pressure within the reaction chamber;
wherein substantially no vaporous by-product accumulates on exposed surfaces of the throttle valve.

44. The method of claim 43, wherein the actuator is selected from the group consisting of a motor assembly, a pneumatic assembly, a hydraulic cylinder, and an electrical solenoid.

45. The method of claim 44, wherein the motor assembly comprises a motor, a carrier, a support, and a lead screw.

46. The method of claim 44, wherein the pneumatic assembly comprises a pneumatic valve, a carrier, and a support, the pneumatic valve having a valve body, a piston, and at least one air aperture.

47. A method of regulating pressure in a reaction chamber of a vapor deposition apparatus, the method comprising the steps of:
providing the deposition apparatus, the deposition apparatus comprising the reaction chamber for receiving one or more gases therein, and a valve device in fluid communication with the reaction chamber, the valve device comprising:
a throttle valve defining a valve chamber and a valve aperture to the valve chamber;
a plug disposed within the valve chamber, the plug sealingly engageable with the valve aperture;
a plug magnet disposed within the plug;
a magnet external to the throttle valve and in magnetic association with the plug magnet; and
an actuator secured to the magnet and operable to move the magnet along the throttle valve;
introducing at least one gas into the reaction chamber and allowing the at least one gas to react;
actuating the actuator, whereby the magnet is moved along the throttle valve resulting in the plug being moved within the valve chamber and into or out of a sealing engagement with the valve aperture to regulate passage of vaporous by-product from the reaction chamber through the valve chamber, thereby regulating the pressure within the reaction chamber;
wherein substantially no vaporous by-product accumulates on exposed surfaces of the throttle valve.

48. The method of claim 47, wherein the actuator of the throttle valve comprises a motor assembly comprising a motor, a carrier, a support, and a lead screw; and the step of actuating the actuator comprises energizing the motor to rotate the lead screw.

49. The method of claim 47, wherein the actuator of the throttle valve comprises a pneumatic assembly comprising a pneumatic valve, a carrier, and a support, the pneumatic valve including a valve body, a piston, and at least one air aperture; and the step of actuating the actuator comprises introducing air into or releasing air from the air aperture to expand or retract the piston.

50. A method of regulating pressure in a reaction chamber of a vapor deposition apparatus, the method comprising the steps of:
providing the deposition apparatus, the deposition apparatus comprising the reaction chamber for receiving one or more gases therein, and a valve device in fluid communication with the reaction chamber, the valve device comprising:
a throttle valve defining a valve chamber and a valve aperture to the valve chamber;
a plug disposed within the valve chamber, the plug sealingly engageable with the valve aperture;
a plug magnet disposed within the plug;
a magnet external to the throttle valve and in magnetic association with the plug magnet; and
an actuator secured to the magnet and operable to move the magnet along the throttle valve;
introducing at least one gas into the reaction chamber and allowing the at least one gas to react;
actuating the motor assembly, whereby the magnet is moved along the throttle valve resulting in the plug being moved within the valve chamber and into or out of a sealing engagement with the valve aperture to regulate passage of vaporous by-product from the reaction chamber through the valve chamber, thereby regulating the pressure within the reaction chamber;
wherein substantially no vaporous by-product accumulates on exposed surfaces of the throttle valve.

51. A method of regulating pressure in a reaction chamber of a vapor deposition apparatus, the method comprising the steps of:
providing the deposition apparatus, the deposition apparatus comprising the reaction chamber for receiving one or more gases therein, and a valve device in fluid communication with the reaction chamber, the valve device comprising:
a throttle valve defining a valve chamber and a valve aperture to the valve chamber;
a plug disposed within the valve chamber, the plug sealingly engageable with the valve aperture;
a plug magnet disposed within the plug;
a magnet external to the throttle valve and in magnetic association with the plug magnet; and
an actuator secured to the magnet and operable to move the magnet along the throttle valve;
introducing at least one gas into the reaction chamber and allowing the at least one gas to react;
actuating the pneumatic assembly, whereby the magnet is moved along the throttle valve resulting in the plug being moved within the valve chamber and into or out of a sealing engagement with the valve aperture to regulate passage of vaporous by-product from the reaction chamber through the valve chamber, thereby regulating the pressure within the reaction chamber;
wherein substantially no vaporous by-product accumulates on exposed surfaces of the throttle valve.

52. A method of regulating pressure in a reaction chamber of a vapor deposition apparatus, the method comprising the steps of:
providing the deposition apparatus, the deposition apparatus comprising the reaction chamber for receiving one or more gases therein, and a valve device in fluid communication with the reaction chamber, the valve device comprising:
a throttle valve defining a valve chamber and a valve aperture to the valve chamber;
a plug disposed within the valve chamber, the plug sealingly engageable with the valve aperture;
a plug magnet disposed within the plug;
a magnet external to the throttle valve and in magnetic association with the plug magnet; and
a selectively actuatable power source associated with the magnet;
introducing at least one gas into the reaction chamber and allowing the at least one gas to react;
actuating the power source associated with the magnet resulting in the plug being moved within the valve chamber and into or out of a sealing engagement with the valve aperture to regulate passage of vaporous by-product from the reaction chamber through the valve chamber, thereby regulating the pressure within the reaction chamber;
wherein substantially no vaporous by-product accumulates on exposed surfaces of the throttle valve.
